(19) United States
(12) Patent Application Publication
(10) Pub. No.: US 2026/0051361 A1
(43) Pub. Date: Feb. 19, 2026

(54) MEMORY DEVICES PERFORMING MEMORY ACCESS OPERATION AND REPAIR OPERATION

(71) Applicant: SK hynix Inc., Icheon-si Gyeonggi-do (KR)

(72) Inventor: Choung Ki SONG, Icheon-si Gyeonggi-do (KR)

(73) Assignee: SK hynix Inc., Icheon-si Gyeonggi-do (KR)

(21) Appl. No.: 18/951,143

(22) Filed: Nov. 18, 2024

(30) Foreign Application Priority Data
Aug. 16, 2024 (KR) 10-2024-0110096

(51) Int. Cl. G11C 29/00; G11C 29/02; G11C 29/52

(52) U.S. Cl. CPC G11C 29/76; G11C 29/022; G11C 29/52

(57) ABSTRACT

A memory device includes a memory chip disposed over a base chip. The base chip includes a cache memory configured to store a first access address and first access data when a failure occurs in the first access data during a first memory access operation, and a repair control circuit configured to perform a cache write operation and a cache read operation on the cache memory when a second access address received in a second memory access operation is the same as addresses stored in the cache memory and configured to perform a core write operation and a core read operation on the memory chip when the second access address is different from the addresses stored in the cache memory.

### CROSS-REFERENCE TO RELATED APPLICATIONS

The present application claims priority under 35 U.S.C. § 119(a) to Korean Patent Application No. 10-2024-0110096, filed in the Korean Intellectual Property Office on Aug. 16, 2024, which application is incorporated herein by reference in its entirety.

### BACKGROUND

### 1. Technical Field

Some embodiments of the present disclosure relate to memory devices that analyze information about a data failure in a memory access operation to perform a repair operation.

### 2. Related Art

Recently, stacked memory systems, such as high bandwidth memory (HBM), have been used in a wide range of applications due to their excellent bandwidth. Unlike conventional memory systems that use parallel data buses, the stacked memory system includes a stacked memory device composed of a base chip and a plurality of slice chips that are interconnected by through silicon vias (hereinafter, referred to as “TSVs”). The stacked memory device includes a physical interface, such as a physical layer (hereinafter, referred to as “PHY”), for communication with a processor. The PHY needs to be designed to ensure high-speed data transmission and efficient communication.

### SUMMARY

The present disclosure may provide a memory device including a memory chip disposed over a base chip, wherein the base chip may include a cache memory configured to store a first access address and first access data when a failure occurs in the first access data during a first memory access operation, and a repair control circuit configured to perform a cache write operation and a cache read operation on the cache memory when a second access address received in a second memory access operation is the same as addresses stored in the cache memory and configured to perform a core write operation and a core read operation on the memory chip when the second access address is not the same as the addresses stored in the cache memory.

In addition, the present disclosure may provide a memory device including a memory chip disposed over a base chip, wherein the base chip may include a storage circuit configured to store an access address when a failure occurs in access data during a memory access operation, and a repair control circuit configured to check the access addresses stored in the storage circuit at set times to determine whether to perform a repair operation.

In addition, the present disclosure may provide a method of performing a memory access operation by a memory chip, including generating failure occurrence information, by a memory controller, when a failure occurs in first access data during a first memory access operation, storing, by a repair control circuit, a first access address and the first access data received during the first memory access operation in a cache memory, based on the failure occurrence information, and performing, by the repair control circuit, a cache write operation or a core write operation when the memory controller receives a store request, a second access address, and second access data.

In addition, the present disclosure may provide a method of performing a repair operation, including generating failure occurrence information, by a memory controller, when a failure occurs in access data during a memory access operation, storing, by the repair control circuit, an access address and the access data received during the memory access operation in a cache memory, based on the failure occurrence information, and checking addresses stored in the cache memory at set times to determine whether to perform the repair operation.

### BRIEF DESCRIPTION OF THE DRAWINGS

FIG. 1 is a block diagram illustrating a memory device according to an embodiment of the present disclosure.

FIG. 2 is a flowchart illustrating an operation based on a failure occurring in access data in a memory access operation of a memory device according to an embodiment of the present disclosure.

FIG. 3 is a flowchart illustrating a storage operation and a load operation performed in a memory access operation of a memory device according to an embodiment of the present disclosure.

FIG. 4 is a flowchart illustrating an operation of checking whether a repair is to be performed and performing a repair operation, which are periodically performed in a memory device and according to an embodiment of the present disclosure.

FIG. 5 is a flowchart illustrating a soft-post package repair operation performed in a memory device according to an embodiment of the present disclosure.

FIG. 6 is a flowchart illustrating a data copy operation in a soft-post package repair operation performed in a memory device according to an embodiment of the present disclosure.

FIG. 7 is a flowchart illustrating a data copy back operation in a soft-post package repair operation performed in a memory device according to an embodiment of the present disclosure.

FIG. 8 is a block diagram illustrating a memory device according to another embodiment of the present disclosure.

FIG. 9 is a flowchart illustrating an operation based on a data failure occurring in a memory access operation of a memory device according to another embodiment of the present disclosure.

FIG. 10 is a flowchart illustrating a memory access operation of a memory device according to another embodiment of the present disclosure.

FIG. 11 is a block diagram illustrating a stacked memory system according to an embodiment of the present disclosure.

### DETAILED DESCRIPTION

In the following description of embodiments, when a parameter is referred to as being “predetermined,” a value of the parameter may be determined in advance when the parameter is used in a process or an algorithm. The value of the parameter may be determined when the process or the algorithm starts or may be determined during a period in which the process or the algorithm is executed.

When an element is referred to as “connected” to another element, the elements may be directly connected or connected to one or more intervening elements between the elements. When two elements are referred to as “directly connected,” no intervening element is between the two elements. When one element is identified as “on” or “over” another element, the elements may directly contact each other or an intervening element may be disposed between the elements. Terms such as “top,” “over,” “on,” “side,” “level,” “column,” “outermost,” and other terms implying relative spatial relationship or orientation are utilized only for the purpose of ease of description or reference to a drawing and are not otherwise limiting.

Various embodiments of the present disclosure are described in more detail with reference to the accompanying drawings. The embodiments are described for illustrative purposes only and are not intended to limit the scope of the present disclosure.

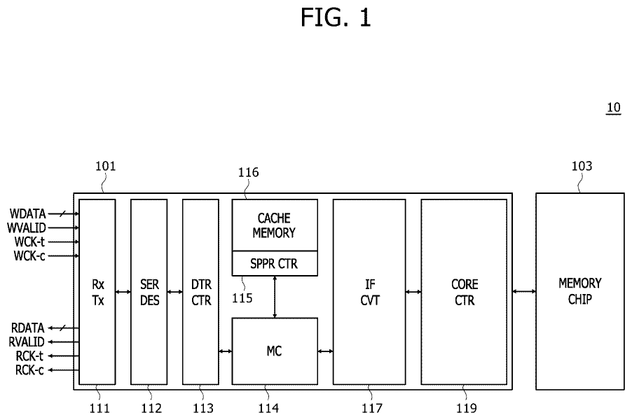

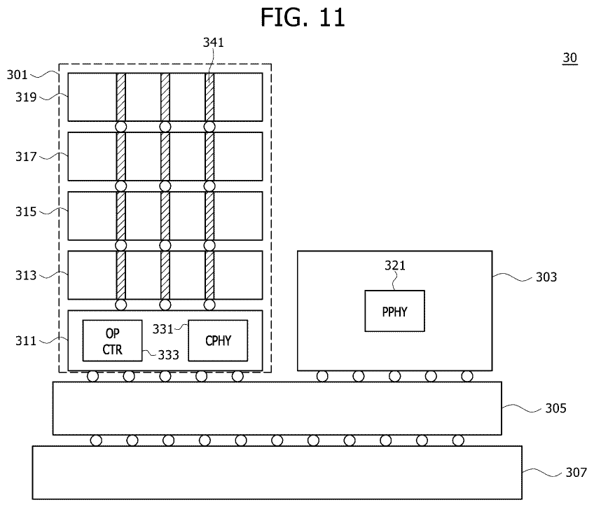

FIG. 1 is a block diagram illustrating a memory device 10 according to an embodiment of the present disclosure. As shown in FIG. 1, the memory device 10 may include a base chip 101 and a memory chip 103. The memory chip 103 may be disposed over the base chip 101. The memory chip 103 may include a plurality of slice chips (for example, 313, 315, 317, and 319 in FIG. 11). Each of the plurality of slice chips may transmit signals through a through via (for example, 341 in FIG. 11) and may be disposed in a stacked form by being connected through micro-bumps, etc.

The base chip 101 may include a transceiver circuit (RX TX) 111, a serialization-parallelization circuit (SERDES) 112, a transmission control circuit (DTRCTR) 113, a memory controller (MC) 114, a repair control circuit (SPPR CTR) 115, a cache memory 116, an interface conversion circuit (IF CVT) 117, and a core control circuit (CORE CTR) 119.

The transceiver circuit 111 may receive write data WDATA, a write valid signal WVALID, and transmission write clock signals WCK-t and WCK-c from a host for a memory access operation. The write data WDATA may include a store request, a load request, access addresses, and access data. The transceiver circuit 111 may receive read data RDATA, a read valid signal RVALID, and transmission read clock signals RCK-t and RCK-c from the serialization-parallelization circuit 112 through the memory access operation and may transmit the read data RDATA, the read valid signal RVALID, and the transmission read clock signals RCK-t and RCK-c to an external device. The host may be one of a central processing unit (CPU), a graphics processing unit (GPU), and a neural processing unit (NPU). The memory access operation may include a store operation that stores data in the memory chip 103 or the cache memory 116 and a load operation that outputs the data stored in the memory chip 103 or the cache memory 116. The store operation may be performed based on the store request included in the write data WDATA, and the load operation may be performed based on the load request included in write data WDATA. When the store operation is performed, access data may be stored in at least one memory cell accessed by an access address, among the memory cells included in the memory chip 103, or the access data may be stored in a region corresponding to the access address in the cache memory 116. When the load operation is performed, the data stored in at least one memory cell accessed by the access address, among the memory cells included in the memory chip 103, may be output as the access data, or the data stored in the region corresponding to the access address in the cache memory 116 may be output as the access data.

When the write valid signal WVALID is activated in synchronization with the transmission write clock signals WCK-t and WCK-c, the serialization-parallelization circuit 112 may transmit the store request, the access address, and the access data included in the write data WDATA to the memory controller 114 through the transmission control circuit 113. When the write valid signal WVALID is activated in synchronization with the transmission write clock signals WCK-t and WCK-c, the serialization-parallelization circuit 112 may transmit the load request and the access address included in the write data WDATA to the memory controller 114 through the transmission control circuit 113. When a load operation is performed, the serialization-parallelization circuit 112 may generate the read data RDATA, the read valid signal RVALID, and the transmission read clock signals RCK-t and RCK-c, based on the signals received from the memory controller 114 through the transmission control circuit 113, and may transmit the read data RDATA, the read valid signal RVALID, and the transmission read clock signals RCK-t and RCK-c to the transceiver circuit 111.

The memory controller 114 may control the transmission control circuit 113, the repair control circuit 115, and the interface conversion circuit 117 for the memory access operation.

When a failure occurs in the access data during the memory access operation, the memory controller 114 may transmit failure occurrence information to the repair control circuit 115. The memory controller 114 may include an error correction circuit (not shown) to determine whether a failure has occurred in the access data during the memory access operation. The error correction circuit may be implemented to detect whether a failure has occurred using the Hamming Code or Reed-Solomon (RS) code; however, this is merely an example and the present disclosure is not limited thereto. When the failure occurrence information is received from the memory controller 114, the repair control circuit 115 may receive the access address and the access data from the memory controller 114 and may store the access address and the access data in the cache memory 116. In the cache memory 116, the access address and the access data may be stored in corresponding regions.

When a store request, an access address, and access data for a store operation are received through the transmission control circuit 113, the memory controller 114 may transmit the access address to the repair control circuit 115. The repair control circuit 115 may check whether the access address is the same as one of the addresses stored in the cache memory 116. When the access address is the same as one of the addresses stored in the cache memory 116, the repair control circuit 115 may receive the access data from the memory controller 114 and may perform a cache write operation that stores the access data in the region corresponding to the access address in the cache memory 116. When the access address is not the same as one of the addresses stored in the cache memory 116, the repair control circuit 115 may control the memory controller 114 to perform a core write operation. In the core write operation, the memory controller 114 may control the interface conversion circuit 117 such that the access data is stored in at least one memory cell accessed by the access address, among the memory cells included in the memory chip 103.

When a load request and an access address for a load operation are received through the transmission control circuit 113, the memory controller 114 may transmit the access address to the repair control circuit 115. The repair control circuit 115 may check whether the access address is the same as one of the addresses stored in the cache memory 116. When the access address is the same as one of the addresses stored in the cache memory 116, the repair control circuit 115 may control the cache memory 116 and the memory controller 114 to perform a cache read operation. In the cache read operation, the cache memory 116 may output the data stored in the region corresponding to the access address as the access data, and the memory controller 114 may transmit the access data to the transmission control circuit 113. When the access address is not the same as one of the addresses stored in the cache memory 116, the repair control circuit 115 may control the memory controller 114 to perform a core read operation. During the core read operation, the memory controller 114 may control the interface conversion circuit 117 such that the data stored in at least one memory cell accessed by the access address, among the memory cells included in the memory chip 103, is output as the access data.

The repair control circuit 115 may check the access addresses stored in the cache memory 116 at set times to determine whether to perform the repair operation. The repair control circuit 115 may be equipped with a timer (not shown) to determine whether to perform the repair operation at set times. The repair control circuit 115 may control the memory controller 114 such that the repair operation is performed when it is confirmed that a failure has occurred in a set number or more times in memory cells connected to the same word line by the access addresses. The memory controller 114 may perform the repair operation according to the control of the repair control circuit 115. The repair operation performed in the memory controller 114 may be a soft-post package repair performed based on the access address stored in the cache memory 116 but may also be implemented as a hard-post package repair, etc., depending on the embodiment. The memory controller 114 may receive information regarding a word line requiring the repair operation from the repair control circuit 115 and may perform the repair operation on the memory cells connected to the word line. For example, the memory controller 114 may sequentially access the memory cells connected to the word line requiring the repair operation based on a target address to store the data stored in the memory cells in the cache memory 116, replace the word line requiring the repair operation with a redundancy word line, and then copy back the data of the memory cells stored in the cache memory 116 to the memory cells connected to the replaced redundancy word line. The repair control circuit 115 may receive confirmation from the memory controller 114 that the repair operation has ended and may delete the access addresses of the memory cells from the cache memory 116 that are connected to the replaced word lines based on the repair operation.

The interface conversion circuit 117 may convert the interface of the control signal transmitted from the memory controller 114 during the core write operation and the core read operation according to the control of the memory controller 114 to transmit the control signal to the core control circuit 119.

The core control circuit 119 may perform the core write operation that stores the access data in at least one memory cell accessed by the access address, among the memory cells included in the memory chip 103, or may perform the core read operation that outputs the data stored in at least one memory cell accessed by the access address, among the memory cells included in the memory chip 103, as the access data according to the control signal, the interface of which has been converted in the interface conversion circuit 117.

When the core write operation is performed, the core control circuit 119 may store the access data received from the interface conversion circuit 117 in at least one memory cell accessed by the access address, among the memory cells included in the memory chip 103. When the core read operation is performed, the core control circuit 119 may output the data stored in the at least one memory cell accessed by the access address, among the memory cell included in the memory chip 103, to the interface conversion circuit 117.

The memory device 10, configured as described above, may store the access address and may access data in the cache memory 116 when a failure occurs in the access data during the memory access operation, and the memory device 10 may perform a cache write operation and a cache read operation for the access address and access data stored in the cache memory 116 when the memory access operation is performed for the memory cell in which a data failure has occurred, thereby performing the memory access operation quickly. In addition, the memory device 10 may check and respond to defects in the memory device in advance by periodically checking the access addresses stored in the cache memory 116 to determine whether to perform a repair operation.

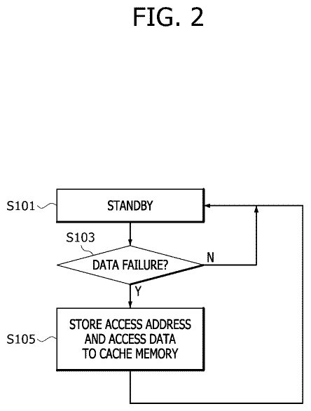

FIG. 2 is a flowchart illustrating an operation based on a data failure occurring in a memory access operation of the memory device 10 shown in FIG. 1.

Referring to FIG. 1 and FIG. 2, the operation that is performed when the data failure occurs in the memory access operation is as follows.

First, the memory device 10 may be in a standby state (S101). Second, while in the standby state (S101), the memory controller 114 may determine whether a failure has occurred in the access data during the memory access operation (S103).

Next, when failure occurrence information is received from the memory controller 114, the repair control circuit 115 may receive an access address and access data from the memory controller 114 and may store the access address and access data in the cache memory 116 (S105).

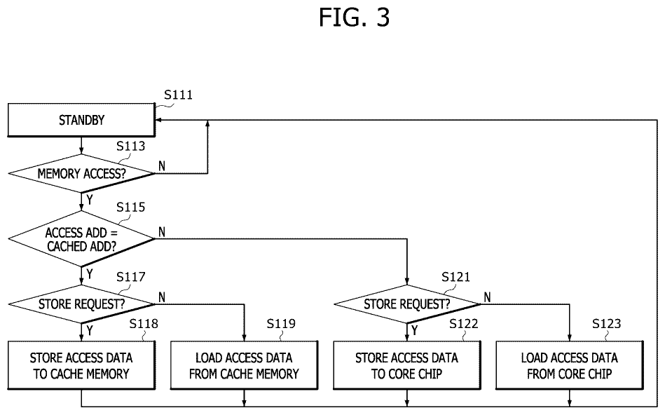

FIG. 3 is a flowchart illustrating a store operation and a load operation performed in the memory access operation of the memory device 10 shown in FIG. 1.

Referring to FIG. 1 and FIG. 3, a cache memory operation may be performed as follows.

In a standby state (S111), the memory controller 114 may determine whether the memory access operation is to be performed (S113), and when the memory access operation is performed, the memory controller 114 may transmit the access address to the repair control circuit 115 through the transmission control circuit 113.

The repair control circuit 115 may check whether the access address is the same as one of the addresses stored in the cache memory 116 (S115).

When the access address is the same as one of the addresses stored in the cache memory 116, the repair control circuit 115 may check whether the memory controller 114 has received a store request for a store operation from the memory controller 114 (S117). When the memory controller 114 receives the store request, the repair control circuit 115 may receive the access data from the memory controller 114 and may control a cache write operation to be performed to store the access data in a region corresponding to the access address in the cache memory 116 (S118). Meanwhile, when the access address is the same as one of the addresses stored in the cache memory 116 and the memory controller 114 has not received the store request (when a load request for a load operation has been received instead), the repair control circuit 115 may perform a cache read operation that outputs the data stored in the region corresponding to the access address in the cache memory 116 as the access data (S119).

When the access address is not the same as one of the addresses stored in the cache memory 116, the repair control circuit 115 may check whether the memory controller 114 has received the store request from the memory controller 114 (S121). When the memory controller 114 receives the store request, the repair control circuit 115 may control the memory controller 114 to perform a core write operation. In the core write operation, the memory controller 114 may control the interface conversion circuit 117 such that the access data is stored in at least one memory cell accessed by the access address, among the memory cells included in the memory chip 103 (S122). Meanwhile, when the access address is not the same as one of the addresses stored in the cache memory 116 and the memory controller 114 has not received the store request (when the load request for the load operation has been received instead), the repair control circuit 115 may control the memory controller 114 to perform a core read operation. During the core read operation, the memory controller 114 may control the interface conversion circuit 117 such that the data stored in at least one memory cell accessed by the access address, among the memory cells included in the memory chip 103, is output as the access data (S123).

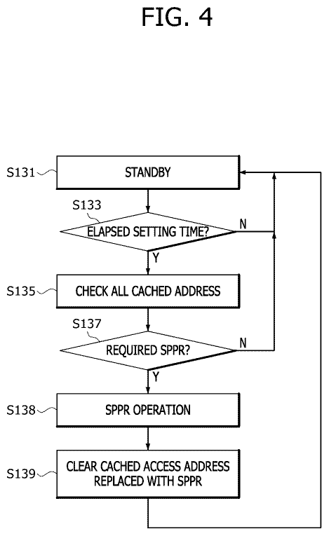

FIG. 4 is a flowchart illustrating an operation of checking whether a repair is to be performed and performing a repair operation, which are periodically performed in the memory device 10 shown in FIG. 1.

Referring to FIG. 1 and FIG. 4, the operation of checking whether a repair is to be performed and performing the repair operation are as follows.

First, in a standby state (S131), the repair control circuit 115 may determine whether a set time has elapsed (S133). When the set time has elapsed, the repair control circuit 115 may check all access addresses stored in the cache memory 116 (S135).

Next, the repair control circuit 115 may determine whether a repair operation is necessary based on the checking of the access addresses (S137). Based on the access addresses, the repair control circuit 115 may control the memory controller 114 such that a repair operation is performed when it is confirmed that a failure has occurred in a set number or more memory cells connected to the same word line. The memory controller 114 may perform a soft-post package repair operation based on the access addresses stored in the cache memory 116 (S138). The repair control circuit 115 may receive confirmation from the memory controller 114 that the repair operation has ended and may delete the access addresses of the memory cells from the cache memory 116 that are connected to the replaced word line based on the soft-post package repair operation (S139).

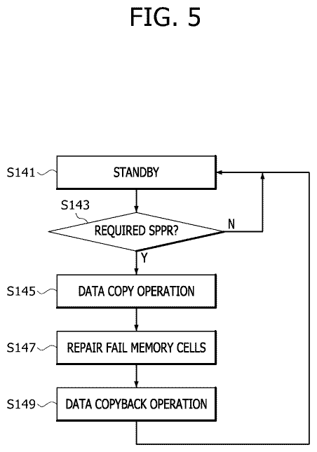

FIG. 5 is a flowchart illustrating the soft-post package repair operation performed in the memory device 10 shown in FIG. 1.

Referring to FIG. 1 and FIG. 5, the soft-post package repair operation is performed as follows.

First, in a standby state (S141), the repair control circuit 115 may determine whether the soft-post package repair operation is required (S143). When it is determined that the soft-post package repair operation is required, the memory controller 114 may be controlled by the repair control circuit 115 to perform the soft-post package repair operation. In the soft-post package repair operation, a data copy operation (S145), a failed memory cell repair operation (S147), and a data copy back operation (S149) may be sequentially performed. The data copy operation (S145) may be performed by storing the data stored in the memory cells requiring the repair operation in the cache memory 116. The failed memory cell repair operation (S147) may be performed by replacing the word lines connected to the memory cells requiring the repair operation with redundancy word lines. Before the memory cells are connected to the redundancy word line, the data copy back operation (S149) may be performed by copying back the data stored in the cache memory 116 during the data copy operation S145.

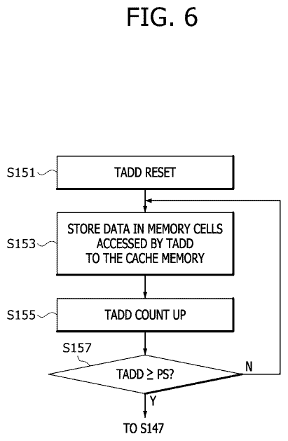

FIG. 6 is a flowchart illustrating the data copy operation performed in the repair operation.

Referring to FIG. 1 and FIG. 6, the data copy operation may be performed as follows.

First, the memory controller 114 may initialize a target address TADD (S151). The initialized target address TADD may be set as the address for accessing a first memory cell connected to the word line requiring a repair operation. The repair control circuit 115 may store data of the memory cell accessed by the target address TADD that is initialized by the memory controller 114 in the cache memory 116 (S153).

Next, the memory controller 114 may sequentially count up the target address TADD (S155), and the repair control circuit 115 may store the data of the memory cell accessed by the target address TADD that is counted up by the memory controller 114 in the cache memory 116. Whenever the target address TADD is counted up, the memory cell accessed by the counted target address TADD may be changed from a second memory cell connected to the word line requiring the repair operation to a last memory cell.

Next, the memory controller 114 may determine whether the counted target address TADD is greater than or equal to a predetermined size PS (S157). When the target address TADD is greater than or equal to the predetermined size PS, it means that the memory cell accessed by the counted target address TADD is the last memory cell connected to the word line requiring the repair operation. Therefore, when the counted target address TADD is greater than or equal to the predetermined size, the memory controller 114 may end the data copy operation and may perform a failed memory cell repair operation (S147).

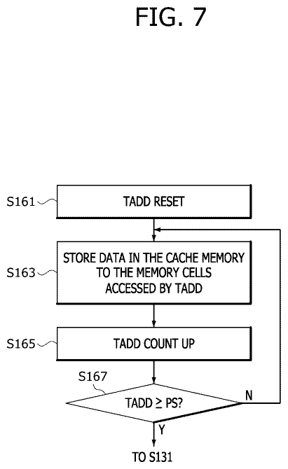

FIG. 7 is a flowchart illustrating a data copy back operation performed in a repair operation.

Referring to FIG. 1 and FIG. 7, the data copy back operation may be performed as follows.

First, the memory controller 114 may initialize the target address TADD (S161). The initialized target address TADD may be set as an address for accessing a first memory cell connected to the redundancy word line replaced during the repair operation. The repair control circuit 115 may store the data stored in the cache memory 116 in the memory cell accessed by the target address TADD that is initialized by the memory controller 114. In this case, the data stored in the cache memory 116 may be set as the data stored in the first memory cell connected to the word line; however, this is only an example and the present disclosure is not limited thereto (S163).

Next, the memory controller 114 may sequentially count up the target data TADD, and the repair control circuit 115 may store the data stored in the cache memory 16 in the memory cell accessed by the target address TADD that is counted up by the memory controller 114. Whenever the target address TADD is counted up, the memory cell accessed by the counted target address TADD may be changed from the second memory cell connected to the redundancy word line to the last memory cell, and the data stored in the cache memory 116 may also be changed from the data stored in the second memory cell connected to the word line to data stored in the last memory cell; however, this is only an example and the present disclosure is not limited thereto.

Next, the memory controller 114 may determine whether the counted target address TADD is greater than or equal to a predetermined size PS (S167). When the target address TADD is greater than or equal to the predetermined size PS, it means that the memory cell accessed by the counted-up target address TADD is the last memory cell connected to the redundancy word line. Therefore, when the counted-up target address TADD is greater than or equal to the predetermined size PS, the memory controller 114 may end the data copy back operation and may control the memory device 10 to enter the standby state (S131).

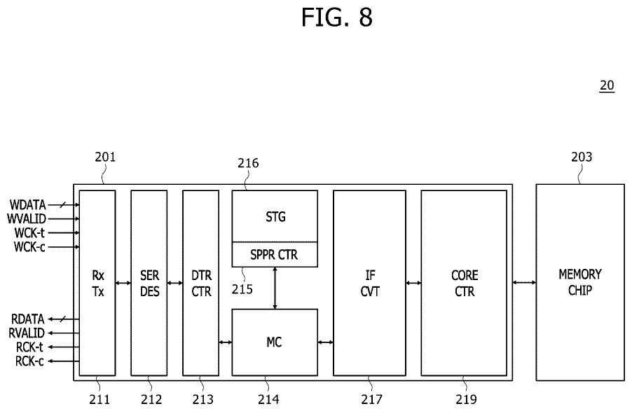

FIG. 8 is a block diagram illustrating a memory device 20 according to another embodiment of the present disclosure. As shown in FIG. 8, the memory device 20 may include a base chip 201 and a memory chip 203. The memory chip 203 may be disposed over the base chip 201. The memory chip 203 may include a plurality of memory chips 203. The plurality of memory chips 203 may be connected to each other through through-vias (for example, 341 in FIG. 11) and may be disposed in a stacked form.

The base chip 201 may include a transceiver circuit (RX TX) 211, a serialization-parallelization circuit (SERDES) 212, a transmission control circuit (DTRCTR) 213, a memory controller (MC) 214, a repair control circuit (SPPR CTR) 215, a storage circuit 216, an interface conversion circuit (IF CVT) 217, and a core control circuit (CORE CTR) 219.

The transceiver circuit 211 may receive write data WDATA, a write valid signal WVALID, and transmission write clock signals WCK-t and WCK-c applied from a host for a memory access operation. The write data WDATA may include a store request, a load request, access addresses, and access data. The transceiver circuit 211 may receive read data RDATA, a read valid signal RVALID, and transmission read clock signals RCK-t and RCK-c from the serialization-parallelization circuit 212 during the memory access operation and may transmit the read data RDATA, the read valid signal RVALID, and the transmission read clock signals RCK-t and RCK-c to an external device. The memory access operation may include a store operation that stores data in the memory chip 203 and a load operation that outputs the data stored in the memory chip 203. The store operation may be performed by the store request included in the write data WDATA, and the load operation may be performed by the load request included in the write data WDATA. When the store operation is performed, the access data may be stored in at least one memory cell accessed by the access address, among the memory cells included in the memory chip 203. When the load operation is performed, the data stored in at least one memory cell accessed by the access address, among the memory cells included in the memory chip 203, may be output as the access data.

When the write valid signal WVALID is activated in synchronization with the transmission write clock signals WCK-t and WCK-c, the serialization-parallelization circuit 212 may transmit the store request, the access addresses, and the access data included in the write data WDATA to the memory controller 214 through the transmission control circuit 213. When the write valid signal WVALID is activated in synchronization with the transmission write clock signals WCK-t and WCK-c, the serialization-parallelization circuit 212 may transmit the load request and the access addresses included in the write data WDATA to the memory controller 214 through the transmission control circuit 213. When a load operation is performed, the serialization-parallelization circuit 212 may generate the read data RDATA, the read valid signal RVALID, and the transmission read clock signals RCK-t and RCK-c, based on the signal received from the memory controller 214 through the transmission control circuit 213, and may transmit the read data RDATA, the read valid signal RVALID, and the transmission read clock signals RCK-t and RCK-c to the transceiver circuit 211.

The memory controller 214 may control the transmission control circuit 213, the repair control circuit 215, and the interface conversion circuit 217 for the memory access operation.

When a failure occurs in the access data during the memory access operation, the memory controller 214 may transmit failure occurrence information to the repair control circuit 215. The memory controller 214 may include an error correction circuit (not shown) to determine whether a failure has occurred in the access data during the memory access operation. The error correction circuit may be implemented to detect whether a failure has occurred using the Hamming Code or the Reed-Solomon (RS) code; however, this is only an example and the present disclosure is not limited thereto. When the failure occurrence information is received from the memory controller 214, the repair control circuit 215 may receive the access address from the memory controller 214 to store the access address in the storage circuit 216. The storage circuit 216 may be implemented with an SRAM device; however, this is only an example and the present disclosure is not limited thereto.

When a store request, an access address, and access data for a store operation are received through the transmission control circuit 213, the memory controller 214 may transmit the access address to the repair control circuit 215. The repair control circuit 215 may check whether the access address is the same as one of the addresses stored in the storage circuit 216. When the access address is not the same as one of the addresses stored in the storage circuit 216, the repair control circuit 215 may control the memory controller 214 to perform a core write operation. In the core write operation, the memory controller 214 may store the access data in at least one memory cell accessed by the access address, among the memory cells included in the memory chip 203.

When the load request and the access address for the load operation are received through the transmission control circuit 213, the memory controller 214 may transmit the access address to the repair control circuit 215. The repair control circuit 215 may check whether the access address is the same as one of the addresses stored in the storage circuit 216. When the access address is the same as one of the addresses stored in the storage circuit 216, the repair control circuit 215 may store the access address received from the memory controller 214 in the storage circuit 216. When the access address is not the same as one of the addresses stored in the storage circuit 216, the repair control circuit 215 may control the memory controller 214 to perform a core read operation. During the core read operation, the memory controller 214 may control the interface conversion circuit 217 such that the data stored in at least one memory cell accessed by the access address, among the memory cells included in the memory chip 203, is output as the access data.

The repair control circuit 215 may check the access addresses stored in the storage circuit 216 at set times to determine whether to perform a repair operation. The repair control circuit 215 may be equipped with a timer (not shown) to determine whether to perform the repair operation at set times. When it is confirmed that a failure has occurred in a number of memory cells that is equal to or greater than a set number connected to the same word line by the access addresses, the repair control circuit 215 may control the memory controller 214 to perform a repair operation. The memory controller 214 may perform the repair operation according to the control of the repair control circuit 215. The repair operation performed in the memory controller 214 may be a soft-post package repair operation performed based on the access addressed stored in the storage circuit 216, but the repair operation may also be implemented as a hard-post package repair operation, etc., depending on the embodiment. The memory controller 214 may receive information regarding the word line requiring the repair operation from the repair control circuit 215 and may perform the repair operation on the memory cells connected to the word line. For example, the memory controller 214 may sequentially access the memory cells connected to the word line requiring the repair operation based on a target address to store the data stored in the memory cells in the storage circuit 216, replace the word line requiring the repair operation with a redundancy word line, and then copy back the data of the memory cells stored in the storage circuit 216 to the memory cells connected to the replaced redundancy word line. The repair control circuit 215 may receive confirmation from the memory controller 214 that the repair operation has ended and may delete the access addresses of the memory cells from the storage circuit 216 that are connected to the word line replaced based on the repair operation.

The interface conversion circuit 217 may convert the interface of the control signal transmitted from the memory controller 214 to the core control circuit 219 during the core write operation and the core read operation according to the control of the memory controller 214.

The core control circuit 219 may perform the core write operation that stores the access data in at least one memory cell accessed by the access address, among the memory cells included in the memory chip 203, or may perform the core read operation that outputs the data stored in at least one memory cell accessed by the access address, among the memory cells included in the memory chip 203, as the access data according to the control signal, the interface of which has been converted in the interface conversion circuit 217.

When the core write operation is performed, the core control circuit 219 may store the access data received from the interface conversion circuit 217 in at least one memory cell accessed by the access address, among the memory cells included in the memory chip 203. When the core read operation is performed, the core control circuit 219 may output the data stored in the at least one memory cell accessed by the access address, among the memory cell included in the memory chip 203, to the interface conversion circuit 217.

The memory device 20, configured as described above, may store the access address in the storage circuit 216 when a failure occurs in the access data during a memory access operation, and the memory device 20 may periodically check the access addresses stored in the storage circuit 216 to determine whether to perform a repair operation, thereby detecting defects in the memory device 20 in advance and responding to the defects.

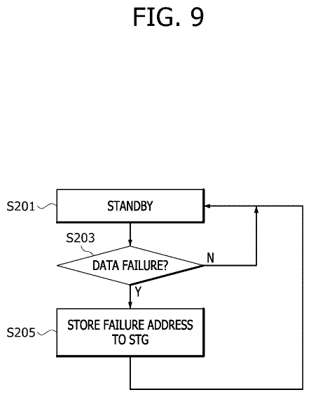

FIG. 9 is a flowchart illustrating an operation based on a data failure occurring in the memory access operation of the memory device 20 shown in FIG. 8.

Referring to FIG. 8 and FIG. 9, the operation, when the data failure occurs in the memory access operation is performed as follows.

First, in a standby state (S201), the memory controller 214 may determine whether a failure has occurred in the access data during the memory access operation (S203).

Next, when the repair control circuit 215 receives failure occurrence information from the memory controller 214, the repair control circuit 215 may receive an access address from the memory controller 214 and may store the access address in the storage circuit 216 (S205).

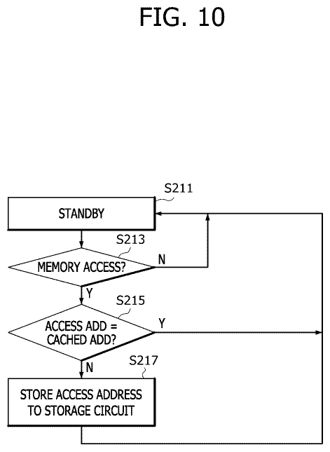

FIG. 10 is a flowchart illustrating the memory access operation of the memory device 20 shown in FIG. 8.

Referring to FIG. 8 and FIG. 9, the memory access operation is performed as follows.

In a standby state (S211), the memory controller 214 may determine whether the memory access operation is to be performed (S213), and when the memory access operation is not performed, the memory controller 214 may transmit an access address to the repair control circuit 215 through the transmission control circuit 213. The repair control circuit 215 may check whether the access address is the same as one of the addresses stored in the storage circuit 216 (S215). When the access address is not the same as one of the addresses stored in the storage circuit 216, the repair control circuit 215 may store the access address received from the memory controller 214 in the storage circuit 216 (S217).

FIG. 11 is a block diagram illustrating a stacked memory system 30 according to an embodiment of the present disclosure.

As shown in FIG. 11, the stacked memory system 30 may include a stacked memory device 301, a processor 303, an interposer 305, and a substrate 307.

The interposer 305 may be disposed over the substrate 307, and the stacked memory device 301 and the processor 303 may be disposed over the interposer 305. The interposer 305 may be used to electrically connect the substrate 307, the stacked memory device 301, and the processor 303 to each other. Because the pitch differences of the substrate 307, the stacked memory device 301, and the processor 303 are large, the substrate 307, the stacked memory device 301, and the processor 303 may be electrically connected using the interposer 305 including variously formed wires.

The processor 303 may include a processor interface circuit (PPHY) 321. The processor 303 may apply a write control signal including commands and addresses for controlling various internal operations of the stacked memory device 301 to the stacked memory device 301 through the processor interface circuit 321 and may receive a read control signal from the stacked memory device 301 through the processor interface circuit 321. The write control signal may include the write data WDATA, the write valid signal WVALID, and the transmission write clock signals WCK-t and WCK-c shown in FIG. 1 and FIG. 8. The read control signal may include the read data RDATA, the read valid signal RVALID, and the transmission read clock signals RCK-t and RCK-c shown in FIG. 1 and FIG. 8.

The stacked memory device 301 may include a base chip 311 and slice chips 314, 315, 317, and 319. The stacked memory device 301 may be implemented with the stacked memory device 20 shown in FIG. 1 and FIG. 8.

The slice chips 314, 315, 317, and 319 may be sequentially stacked over the base chip 311 and may receive various signals from the base chip 311 through through-vias 341.

The base chip 311 may include a core interface circuit (CPHY) 331 and an operation control circuit (OP CTR) 333. The core interface circuit 331 may be configured to communicate with the processor interface circuit 321 to transmit the write control signals transmitted from the processor 303 to the operation control circuit 333 and to apply the read control signals generated in the operation control circuit 333 to the processor 303.

A limited number of possible embodiments for the present teachings have been presented above for illustrative purposes. Those of ordinary skill in the art will appreciate that various modifications, additions, and substitutions are possible. While this patent document contains many specifics, these should not be construed as limitations on the scope of the present teachings or of what may be claimed, but rather as descriptions of features that may be specific to particular embodiments. Certain features that are described in this patent document in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

What is claimed is:

1. A memory device comprising a memory chip disposed over a base chip,
wherein the base chip comprises:
a cache memory configured to store a first access address and first access data when a failure occurs in the first access data during a first memory access operation; and
a repair control circuit configured to perform a cache write operation and a cache read operation on the cache memory when a second access address received in a second memory access operation is the same as addresses stored in the cache memory and configured to perform a core write operation and a core read operation on the memory chip when the second access address is different from the addresses stored in the cache memory.

2. The memory device of claim 1, further comprising a memory controller, in the first memory access operation, configured to:
receive the first access address and the first access data through a transmission circuit,
transmit failure occurrence information to the repair control circuit when a failure occurs in the first access data, and
transmit the first access address and the first access data to the repair control circuit.

3. The memory device of claim 2, wherein the memory controller is configured to transmit the second access address and second access data to the repair control circuit when a store request, the second access address, and the second access data are received through the transmission control circuit during the second memory access operation.

4. The memory device of claim 3, wherein, when the second access address is the same as one of the addresses stored in the cache memory, the repair control circuit is configured to perform the cache write operation that stores the second access data in a region corresponding to the second access address in the cache memory.

5. The memory device of claim 3, wherein, when the second access address is different from the addresses stored in the cache memory, the memory controller is configured to perform the core write operation that stores the second access data in at least one memory cell accessed by the second access address, among memory cells included in the memory chip.

6. The memory device of claim 2, wherein the memory controller is configured to transmit the second access address to the repair control circuit when a load request and the second access address are received through the transmission control circuit during the second memory access operation.

7. The memory device of claim 6, wherein, when the second access address is the same as one of the addresses stored in the cache memory, the repair control circuit is configured to perform a cache read operation that outputs data stored in a region corresponding to the second access address in the cache memory.

8. The memory device of claim 6, wherein, when the second access address is different from the addresses stored in the cache memory, the memory controller is configured to perform a core read operation of outputting the data stored in at least one memory cell accessed by the access address, among memory cells included in the memory chip.

9. The memory device of claim 1, wherein the repair control circuit is configured to check the access addresses stored in the cache memory at set times to determine whether to perform a repair operation.

10. The memory device of claim 9, wherein the repair control circuit is configured to control the memory controller such that the repair operation is performed when it is confirmed that a failure occurs in a number of memory cells that is equal to greater than a set number, connected to the same word line, based on the addresses stored in the cache memory.

11. The memory device of claim 10, wherein, when the repair operation is performed, the memory controller is configured to receive information on a word line requiring the repair operation from the repair control circuit to perform the repair operation on the memory cells connected to the word line.

12. The memory device of claim 1, wherein the memory controller is configured to:
sequentially access memory cells connected to the word line requiring the repair operation to store data stored in the memory cells in the cache memory;
replace the word line requiring the repair operation with a redundancy word line; and
copy back the data stored in the cache memory in the memory cells connected to the redundancy word line.

13. The memory device of claim 12, wherein the repair control circuit is configured to:
receive confirmation that the repair operation is completed from the memory controller, and
delete the address from the cache memory for the replaced word line based on the repair operation.

14. A memory device comprising a memory chip disposed over a base chip,
wherein the base chip comprises:
a storage circuit configured to store access addresses when a failure occurs in access data during a memory access operation; and
a repair control circuit configured to check the access addresses stored in the storage circuit at set times to determine whether to perform a repair operation.

15. The memory device of claim 14, further comprising a memory controller, in the memory access operation, configured to:
receive the access address and the access data through a transmission circuit,
transmit failure occurrence information to the repair control circuit when a failure occurs in the access data, and
transmit the access address to the repair control circuit.

16. The memory device of claim 15, wherein the repair control circuit is configured to control the memory controller such that the repair operation is performed when it is confirmed that a failure occurs in a number of memory cells that is equal to or greater than a set number, connected to the same word line, based on the addresses stored in the storage circuit.

17. The memory device of claim 16, wherein the memory controller is configured to receive information on the word line requiring the repair operation from the repair control circuit and configured to perform the repair operation on the memory cells connected to the word line when the repair operation is performed.

18. The memory device of claim 14, wherein the memory controller is configured to:
sequentially access memory cells connected to the word line requiring the repair operation to store data stored in the memory cells in the cache memory;
replace the word line requiring the repair operation with a redundancy word line; and
copy back the data stored in the cache memory in the memory cells connected to the redundancy word line.

19. The memory device of claim 18, wherein the repair control circuit is configured to:
receive confirmation that the repair operation is completed from the memory controller, and
delete the address from the storage circuit for the replaced word line based on the repair operation.

20. A method of performing a memory access operation by a memory chip, the method comprising:
generating failure occurrence information, by a memory controller, when a failure occurs in first access data during a first memory access operation;
storing, by a repair control circuit, a first access address and the first access data received during the first memory access operation in a cache memory, based on the failure occurrence information; and
performing, by the repair control circuit, a cache write operation or a core write operation when the memory controller receives a store request, a second access address, and second access data.

21. The method of claim 20, wherein, when the second access address is the same as one of the addresses stored in the cache memory, the repair control circuit is configured to perform the cache write operation that stores the second access data in a region corresponding to the second access address in the cache memory.

22. The method of claim 20, wherein, when the second access address is different from the addresses stored in the cache memory, the memory controller is configured to perform the core write operation that stores the second access data in at least one memory cell accessed by the second access address, among memory cells included in the memory chip.

23. The method of claim 20, further comprising performing a cache read operation or a core read operation, by the repair control circuit, when the memory controller receives a load request and a third access address.

24. The method of claim 23, wherein, when the third access address is the same as one of the addresses stored in the cache memory, the repair control circuit is configured to perform the cache read operation that outputs data stored in the region corresponding to the third access address in the cache memory as third access data.

25. The method of claim 23, wherein, when the third access address is different from the addresses stored in the cache memory, the memory controller is configured to perform the core read operation that outputs data stored in at least one memory cell accessed by the third access address, among memory cells included in the memory chip, as third access data.

26. A method of performing a repair operation, the method comprising:
generating failure occurrence information, by a memory controller, when a failure occurs in access data during a memory access operation;
storing, by the repair control circuit, an access address and the access data received during the memory access operation in a cache memory, based on the failure occurrence information; and
checking addresses stored in the cache memory at set times to determine whether to perform the repair operation.

27. The method of claim 26, further comprising controlling, by the repair control circuit, the memory controller such that the repair operation is performed when it is confirmed that a failure occurs in a number of memory cells that is equal to or greater than a set number, connected to the same word line, based on the addresses stored in the cache memory.

28. The method of claim 27, further comprising receiving, by the memory controller, information on a word line requiring the repair operation from the repair control circuit and performing, by the memory controller, the repair operation on the memory cells connected to the word line when the repair operation is performed.

29. The method of claim 28, wherein the memory controller is configured to:
sequentially access memory cells connected to the word line requiring the repair operation to store data stored in the memory cells in the cache memory,
replace the word line requiring the repair operation with a redundancy word line, and
copy back the data stored in the cache memory in the memory cells connected to the redundancy word line.

30. The method of claim 29, wherein the repair control circuit is configured to:
receive confirmation that the repair operation is completed from the memory controller, and
delete the address from the cache memory for the replaced word line based on the repair operation.
